(19) United States
(12) Patent Application Publication
(10) Pub. No.: US 2007/0224790 A1
(43) Pub. Date: Sep. 27, 2007

(54) Zn ion implanting method of nitride semiconductor

(75) Inventor: Chong-Don Kim, Seongnam-si (KR)

Correspondence Address: MCDERMOTT WILL & EMERY LLP, 600 13TH STREET, N.W., WASHINGTON, DC, 20005-3096, US

(73) Assignee: SAMSUNG CORNING CO., LTD.

(21) Appl. No.: 11/723,581

(22) Filed: Mar. 21, 2007

(30) Foreign Application Priority Data
Mar. 22, 2006 (KR) 10-2006-0025977

(51) Int. Cl. H01L 21/04

(52) U.S. Cl. 438/510

(57) ABSTRACT

A method of implanting a zinc (Zn)-ion into a nitride-based semiconductor substrate, the method includes: providing a homogeneous substrate on which a gallium nitride layer is grown; placing the homogeneous substrate in a crucible in which gallium nitride powders are coated; placing the crucible into a furnace; and performing a heat treatment process, so that a Zn-ion implantation is performed under an ammoniacal atmosphere in the furnace. The method of implanting a Zn-ion into a nitride-based semiconductor substrate, which can minimize a decomposition of a gallium nitride layer during a heat treatment process at a high temperature, easily produce a p-type, and reduce contact resistance between a semiconductor and a metal electrode, is provided.

### CROSS-REFERENCE TO RELATED APPLICATION

This application claims the benefit of Korean Patent Application No. 10-2006-0025977, filed on Mar. 22, 2006, in the Korean Intellectual Property Office, the disclosure of which is incorporated herein by reference.

### BACKGROUND OF THE INVENTION

1. Field of the Invention

The present invention relates to a method of implanting a zinc (Zn)-ion into a nitride-based semiconductor substrate, and more particularly, to a method of implanting a Zn-ion into a nitride-based semiconductor substrate, which can minimize a phenomenon that a gallium nitride layer is decomposed during a heat treatment process of a Zn-ion implantation for increasing a doping concentration of a nitride semiconductor in producing a nitride-based semiconductor substrate.

2. Description of Related Art

A semiconductor light emitting device such as a light emitting diode is produced using a semiconductor material. The semiconductor light emitting device corresponds to any one light source from among many solid-state light sources changing electric energy into light energy. The semiconductor light emitting device has a small volume and a quick response speed, and is resistant against an external impact. Also, the semiconductor light emitting device has a long expected life span and a low driving voltage, and may realize a lightweight and thin type, and minimize a size depending on various application needs. Accordingly, the semiconductor light emitting device becomes an electronic device appearing in daily life.

Currently, a great interest has been concentrated on a light emitting device using a nitride-based semiconductor such as gallium nitride (GaN), aluminum gallium nitride (AlGaN), indium gallium nitride (InGaN), aluminum indium gallium nitride (AlInGaN), and the like, and most light emitting devices are generally produced on homogeneous substrates such as a sapphire substrate, a silicon carbide (SiC) substrate, and the like corresponding to an electrical insulation material, which is different from other light emitting devices using conductive substrates. The homogeneous substrate may be an insulator, and an electrode may be not directly formed on the substrate. It is required that an electrode should be generated to directly and respectively connect with a p-type and an n-type semiconductor layers, so as to produce the light emitting device.

Also, first, a p-type nitride semiconductor material of a III-nitride light emitting diode is fully doped when an epitaxial process is performed. However, most dopants are protected by hydrogen. Accordingly, after a structure for a light emitting diode is formed, an additional activation-heat treatment process is performed to increase a doping concentration of a nitride semiconductor material when the III-nitride light emitting diode, and the like, are produced. Generally, the heat treatment process is performed by a heating method using a furnace or a microwave oven. In this instance, a device such as a light emitting diode, and the like, is placed in a temperature condition corresponding to an appropriate, high temperature, and a hydrogen atom in a material is reduced after a predetermined period of time. Therefore, contact resistance between a semiconductor and a metal electrode is reduced.

After a gallium nitride layer is formed according to a related art, an epitaxial chip is drawn from a process chamber, an epitaxial wafer is placed in a stove so as to heat the epitaxial wafer corresponding to a temperature being in a range of 400° C. to 1000° C. In this instance, a heat treatment process is performed under an ammoniacal atmosphere so as to change high resistance GaN into low resistance GaN, i.e. GaN in which magnesium is doped.

Also, when a heat treatment process for implanting a Zn-ion into the homogeneous substrate at a high temperature 1000° C. is performed during a long period of time, a phenomenon that a surface of a gallium nitride layer is decomposed occurs. In particular, although low resistance may be expected after a long period of heat treatment when forming a p-type layer by Zn-ion implantation, there is a problem that contact resistance between a semiconductor and a metal electrode is increased due to a decomposition of a gallium nitride layer.

Therefore, a method of implanting a Zn-ion into a nitride-based semiconductor substrate, which can minimize a phenomenon that a gallium nitride layer is decomposed during a heat treatment process of a Zn-ion implantation for increasing a doping concentration of a nitride semiconductor in producing a nitride-based semiconductor substrate, is required.

### BRIEF SUMMARY

An aspect of the present invention provides a method of implanting a zinc (Zn)-ion into a nitride-based semiconductor substrate, which can minimize a decomposition of a gallium nitride layer during a heat treatment process at a high temperature, easily produce a p-type, and reduce contact resistance between a semiconductor and a metal electrode.

According to an aspect of the present invention, there is provided a method of implanting a Zn-ion into a nitride-based semiconductor substrate, the method including: providing a homogeneous substrate on which a gallium nitride layer is grown; placing the homogeneous substrate in a crucible in which gallium nitride powders are coated; placing the crucible into a furnace; and performing a heat treatment process, so that a Zn-ion implantation is performed under an ammoniacal atmosphere in the furnace. In this instance, the nitride-based semiconductor substrate may be produced by mixing either one element or two elements selected from the group consisting of bivalent elements such as magnesium (Mg), nickel (Ni), beryllium (Be), cadmium (Cd), and the like, with Zn, so as to produce a p-type layer.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is a configuration diagram illustrating a method of implanting a zinc (Zn)-ion into a nitride-based semiconductor substrate according to an exemplary embodiment of the present invention;

FIG. 2 is a flowchart illustrating a method of implanting a Zn-ion into a nitride-based semiconductor substrate according to an exemplary embodiment of the present invention; and

FIG. 3 is a graph illustrating substrate weight decrease depending upon a heat treatment temperature and an atmosphere condition according to an exemplary embodiment of the present invention.

### DETAILED DESCRIPTION OF EMBODIMENTS

Reference will now be made in detail to exemplary embodiments of the present invention, examples of which are illustrated in the accompanying drawings, wherein like reference numerals refer to the like elements throughout. The exemplary embodiments are described below in order to explain the present invention by referring to the figures.

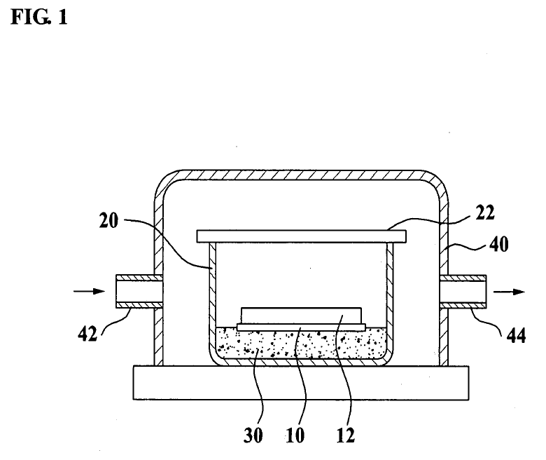

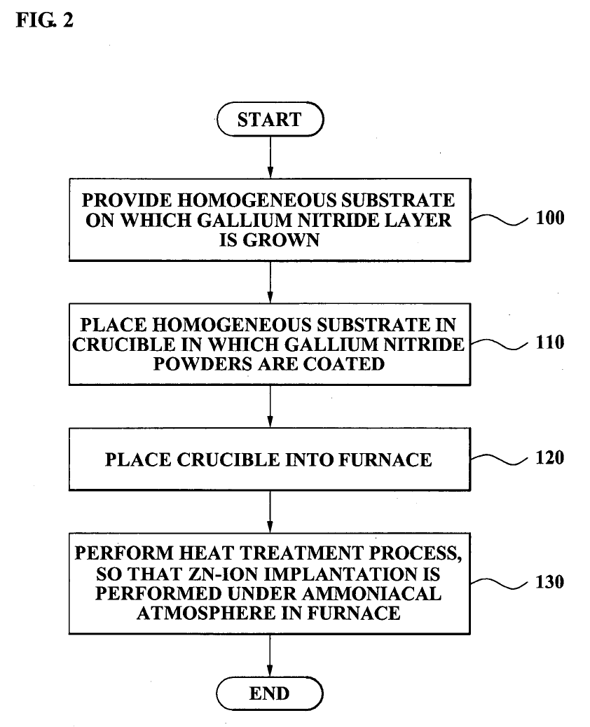

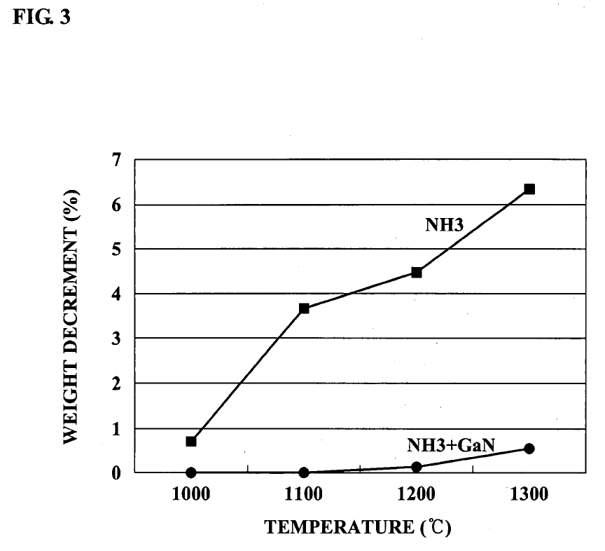

FIG. 1 is a configuration diagram illustrating a method of implanting a zinc (Zn)-ion into a nitride-based semiconductor substrate according to an exemplary embodiment of the present invention. FIG. 2 is a flowchart illustrating a method of implanting a Zn-ion into a nitride-based semiconductor substrate according to an exemplary embodiment of the present invention. FIG. 3 is a graph illustrating substrate weight decrement depending upon a heat treatment temperature and an atmosphere condition according to an exemplary embodiment of the present invention.

When a p-type gallium nitride layer is produced according to an exemplary embodiment of the present invention, a homogeneous substrate 10 is first provided. It is desirable that the homogeneous substrate 10 is transparent, and may be aluminum oxide (Al₂O₃) as an example. Also, any one material selected from sapphire, silicon carbide (SiC), and the like corresponding to an electrical insulation material is used for the homogeneous substrate 10, and it is desirable to use sapphire as a material of the homogeneous substrate 10. Also, the above-described contents may be applied to a method of implanting a Zn-ion into a gallium nitride (GaN)-based homogeneous substrate besides the homogeneous substrate. Also, the nitride-based semiconductor substrate may be used by mixing either one element or two elements selected from the group consisting of bivalent elements such as magnesium (Mg), nickel (Ni), beryllium (Be), cadmium (Cd), and the like, with Zn, so as to produce a p-type layer.

As illustrated in FIG. 1, a homogeneous substrate 10 on which a gallium nitride layer 12 is grown is provided, and the homogeneous substrate 10 on which the gallium nitride layer 12 is grown is placed in a crucible 20.

It is desirable that a space is formed in the crucible 20, and the crucible 20 includes a quartz material resisting a high temperature, and it is more desirable that a cover 22 for isolating an inside and an outside of the crucible 20 is included.

Also, gallium nitride powders 30 are coated in an inner bottom surface of the crucible 20. Accordingly, the homogeneous substrate 10 on which the gallium nitride layer 12 is grown is placed on an upper part of the gallium nitride powders 30, and is hermetically sealed with the cover 22.

Also, the crucible 20 is placed into the furnace 40 for a heat treatment process, and the furnace 40 corresponding to a heating apparatus includes a vapor providing portion 42 which provides carrier vapor and ammonia gas, and a vapor exhaust portion 44 which exhausts vapor to an outside. It is desirable that a heat treatment temperature in the furnace 40 is in the range of 1000° C. to 1300° C., and is higher than 1300° C.

Hereinafter, a method of implanting a Zn-ion into a nitride-based semiconductor substrate, as constructed above, is described as follows.

Referring to the flowchart illustrated in FIG. 2, an operation 100 of providing a homogeneous substrate on which a gallium nitride layer is grown, an operation 110 of placing the homogeneous substrate in a crucible in which gallium nitride powders are coated, an operation 120 of placing the crucible into a furnace, and an operation 130 of performing a heat treatment process, so that a Zn-ion implantation is performed under an ammoniacal atmosphere in the furnace are included.

In this instance, ammonia gas corresponding to 15% to 50% of an entire gas amount, which is provided while a gallium nitride layer is grown, is provided in a state where an inner temperature of the furnace 40 is maintained in the range of about 1000° C. to about 1300° C. via the vapor providing portion 42. In this instance, the gallium nitride powders 30 generate a gallium nitride atmosphere within the crucible 20 which is hermetically sealed with the cover 22 and is heated. Therefore, a decomposition of gallium nitride is minimized in the gallium nitride layer 12 on the homogeneous substrate 10, and a surface by a Zn-ion implantation may be preprocessed.

Accordingly, there are weight decreases of the produced gallium nitride thin films, as illustrated in FIG. 3. Specifically, since a decomposition accomplished with gallium nitride powders under an ammoniacal atmosphere can be minimized, a gallium nitride thin film according to an exemplary embodiment of the present invention may have a great quality due to little weight decrease. However, a conventional gallium nitride thin film, which is generated only under an ammoniacal atmosphere, has much decomposition of gallium nitride, so that weights are significantly changed depending upon temperature rise. For reference, in FIG. 3, solid circles correspond to the present invention and solid squares correspond to the conventional art.

Accordingly, although a heat treatment process is performed during a long period of time for implanting a Zn-ion into the homogeneous substrate, a decomposition of the gallium nitride layer 12 is minimized, and a p-type layer, prevented from being reduced into an n-type deformation, is easily produced. Since a heat treatment process may be performed at a higher temperature, and impurities due to a Zn-ion implantation may be diffused from a surface to a wide area, contact resistance between a semiconductor and a metal electrode is decreased.

According to the present invention, there is provided a method of implanting a Zn-ion into a nitride-based semiconductor substrate, which can minimize a decomposition of a gallium nitride layer during a heat treatment process at a high temperature, easily produce a p-type, and reduce contact resistance between a semiconductor and a metal electrode.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A method of implanting a zinc (Zn)-ion into a nitride-based semiconductor substrate, the method comprising:
providing a homogeneous substrate on which a gallium nitride layer is grown;
placing the homogeneous substrate in a crucible in which gallium nitride powders are coated;
placing the crucible into a furnace; and
performing a heat treatment process, so that a Zn-ion implantation is performed under an ammoniacal atmosphere in the furnace.

2. The method of claim 1, wherein the gallium nitride powders generate a gallium nitride atmosphere within the crucible during the heat treatment process, and minimize a decomposition of the gallium nitride layer on the homogeneous substrate.

3. The method of claim 1, wherein a heat treatment temperature in the furnace is in the range of 1000° C. to 1300° C.

4. The method of claim 1, wherein a heat treatment temperature in the furnace is higher than 1300° C.

5. The method of claim 1, wherein the nitride-based semiconductor substrate is produced by mixing either one element or two elements selected from the group consisting of bivalent elements such as magnesium (Mg), nickel (Ni), beryllium (Be), cadmium (Cd), and the like, with Zn, so as to produce a p-type layer.
